(19) United States
(12) Patent Application Publication
(10) Pub. No.: US 2016/0284879 A1
(43) Pub. Date: Sep. 29, 2016

(54) LIGHT DETECTING DEVICE AND METHOD FOR MANUFACTURING THE SAME

(71) Applicant: UNITED MICROELECTRONICS CORP., HSINCHU (TW)

(72) Inventors: Ming-Han Tsai, Chiayi County (TW); Yuh-Turng Liu, Hsinchu City (TW); Chih-Yun Lin, Hsinchu City (TW); Wei-Ming Ruan, Hsinchu County (TW)

(21) Appl. No.: 14/685,699

(22) Filed: Apr. 14, 2015

(30) Foreign Application Priority Data
Mar. 27, 2015 (CN) 201510139780.2

(51) Int. Cl. H01L 31/0232; H01L 31/18

(52) U.S. Cl. CPC H01L 31/0232; H01L 31/18

(57) ABSTRACT

A light detecting device and a method for manufacturing the same are provided. A light detecting device is provided, comprising a patterned metal layer formed above a substrate; a passivation layer formed above the substrate and exposing portions of the patterned metal layer; a plurality of color filter elements formed on the passivation layer; and a patterned inorganic light filter film formed above the color filter elements. Also, an interlayer can be optionally formed between the color filter elements and the patterned inorganic light filter film.

This application claims the benefit of People's Republic of China application Serial No. 201510139780.2, filed Mar. 27, 2015, the subject matter of which is incorporated herein by reference.

### BACKGROUND

1. Technical Field

The disclosure relates in general to a light detecting device and a method for manufacturing the same, and more particularly to a light detecting device with a light filter film formed after the color filter array and a method for manufacturing the same.

2. Description of the Related Art

Typically, a light sensor is a light detecting device that captures and converts light into an electronic signal. Light sensors can be broadly divided into two groups of image sensors and ambient light sensors. Image sensors are capable of converting an optical image into an electronic signal. Ambient light sensors detect the amount of environmental light (including visible light and infrared light) available and help a processor determine the amount of backlight or illumination for an image sensor in an application, such as displays (ex: LCDs) of electronic products including cell phones and laptop computers, and for various other types of light level measurement and management. By using the ambient light sensor to detect bright and dim ambient light conditions, the backlight of the display can be controllable and adjustable to reduce overall display-system power consumption. Therefore, use of ambient light sensor saves energy for the display and increases lifespan of the display.

Conventional structures of the ambient light sensors and the image sensors still have many problems to be solved. For example, the conventional structure of the color filter elements has large step high issue, and could induce poor coating. Also, it would be difficult to create color filter array above the inorganic film. Furthermore, the edge of color filter must keep a certain distance from the edge of the inorganic film. Therefore, it is one of desirable goals to develop an improved structure of a light detecting device with good properties, such as coating reliable color filter array (CFA) without damage and good uniformity of CFA coating.

### SUMMARY

The disclosure is directed to a light detecting device and a method for manufacturing the same, which improves the element configurations and characteristics of the light detecting device.

According to the disclosure, a light detecting device is provided, comprising a patterned metal layer formed above a substrate; a passivation layer formed above the substrate and exposing portions of the patterned metal layer; a plurality of color filter elements formed on the passivation layer; and a patterned inorganic light filter film formed above the color filter elements. Also, an interlayer can be optionally formed between the color filter elements and the patterned inorganic light filter film.

According to the disclosure, a method for manufacturing a semiconductor device is provided, comprising providing a substrate with a patterned metal layer formed there above; forming a passivation layer above the substrate and exposing portions of the patterned metal layer; forming a plurality of color filter elements on the passivation layer; and forming a patterned inorganic light filter film above the color filter elements.

### BRIEF DESCRIPTION OF THE DRAWINGS

FIG. 1 illustrates a light detecting device according to a first embodiment of the present disclosure.

FIG. 2 illustrates a light detecting device according to a second embodiment of the present disclosure.

FIG. 3A to FIG. 3J illustrate a method for manufacturing a light detecting device according to the second embodiment of the present disclosure.

FIG. 4 illustrates a portion of a patterned inorganic light filter film of a light detecting device according to the embodiment.

FIG. 5 illustrates a light detecting device with micro-lens according to the second embodiment.

FIG. 6 illustrates another light detecting device with micro-lens according to the second embodiment.

### DETAILED DESCRIPTION

In the present disclosure, a light detecting device and a method for manufacturing the same are provided. According to the present invention, the color filter array (CFA) (made by the organic material) is formed before formation of the light filter film (made by the inorganic material). The light detecting device as illustrated by the embodiments possesses several good characteristics. For example, the color filter array damaged by any back-end processes, such as NMP, plasma, solvent treatments, pad re-open step, etc. can be avoided. Also, since the color filter array coating is performed before the inorganic filter film in the embodiments, the defects of rough surface caused by the thick films typically occurred in the conventional structure can be successfully avoided, and better CFA coating control and uniformity can be achieved according to the embodiments. Moreover, the color filter array with the inorganic film formed thereon can be created without worrying poor coating of the color filter array. Thus, the methods as provided in the embodiments simplify the method for manufacturing the light detecting device, and improve the production yield (quality) of the light detecting device.

Two embodiments are provided hereinafter with reference to the accompanying drawings for describing the related configurations and procedures. However, the present disclosure is not limited thereto. It is noted that not all embodiments of the invention are shown. The identical and/or similar elements of the embodiments are designated with the same and/or similar reference numerals. Also, it is noted that there may be other embodiments of the present disclosure which are not specifically illustrated. Modifications and variations can be made without departing from the spirit of the disclosure to meet the requirements of the practical applications. It is also important to point out that the illustrations may not be necessarily be drawn to scale. Thus, the specification and the drawings are to be regard as an illustrative sense rather than a restrictive sense.

### First Embodiment

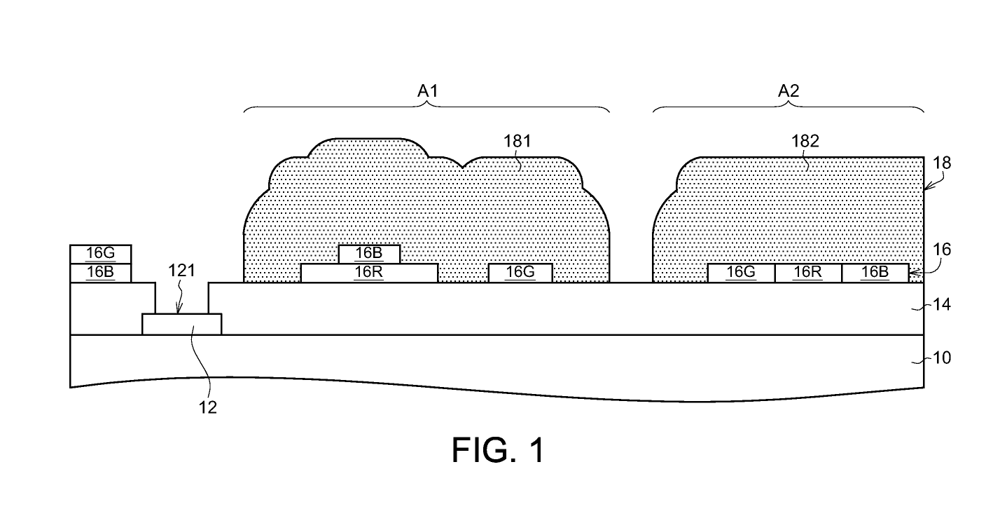

FIG. 1 illustrates a light detecting device according to a first embodiment of the present disclosure. A light detecting device comprises a patterned metal layer 12 formed above a substrate 10, a passivation layer 14 formed above the substrate 10 and exposing portions of the patterned metal layer 12, a plurality of color filter elements 16 formed on the passivation layer 14, and a patterned inorganic light filter film 18 formed above the color filter elements 16. The exposed portions of the patterned metal layer 12 function as the metal pads. In FIG. 1, one metal pad 121 is depicted for exemplification.

In one embodiment, plural photodiodes/transistors (not shown) can be formed on the substrate 10, and an interlayer insulating film (not shown) can be formed on the substrate 10 and the photodiodes/transistors, wherein the passivation film 14 is formed on the interlayer insulating film. Moreover, the color filter elements 16 of the embodiment may include plural red filter elements 16R (of a red color filter layer), plural green filter elements 16G (of a green color filter layer), and plural blue filter elements 16B (of a blue color filter layer). However, it is noted that arrangement of the red, green and blue filter elements 16R, 16G and 16B in FIG. 1 is merely depicted for illustration, not for limitation, and can be altered according to actual needs of the practical application.

In one embodiment, a thickness of a patterned inorganic light filter film 18 is in a range of 2 μm-7 μm. In one embodiment, a thickness of the red, green and blue filter elements 16R, 16G and 16B is in a range of 0.5 μm-2.5 μm. In one embodiment, the color filter elements 16 are formed at a temperature ranged from 25° C. to 280° C. For example, the CF elements 16 are coated at room temperature, and post baked at a higher temperature up to 280° C.

The patterned inorganic light filter film 18 of the embodiment for shielding visible light comprises at least two inorganic light filter films. Three or more inorganic light filter films are also applicable. The inorganic light filter films of the patterned inorganic light filter film 18 can be used for shielding light with different wavelengths for achieving the different purposes of the applications. For example, the patterned inorganic light filter film 18 is able to block the visible light with the wavelength of 400 nm-800 nm and pass the infrared light with the wavelength larger than 800 nm. However, the disclosure is not limited to those exemplifying wavelength ranges, the patterned inorganic light filter film 18 capable for blocking light with other wavelengths (ex: visible light) and allowing pass of light in a specific wavelength range (ex: infrared light) can be used in the applications. In the first embodiment, the patterned inorganic light filter film 18 may comprise a first inorganic film 181 formed at a first light detecting region A1 and a second inorganic film 182 formed at a second light detecting region A2. Additionally, the second inorganic film 182 could be separated from the first inorganic film 181.

In one embodiment, the first light detecting region A1 may comprise at least one stack of the CF elements, such as a green filter element 16G, and a blue filter element 16B stacked on a red filter element 16R. Also, the second light detecting region A2 may comprise several CF elements arranged in an array, such as an array of the green filter element 16G, the red filter element 16R and the blue filter element 16B, as shown in FIG. 1. The first light detecting region A1 and the second light detecting region A2 can be respectively corresponding to the ambient light sensor (ALS) region and the image sensor region, or both corresponding to the ALS region or the image sensor region, depending on the actual needs of the practical applications, and the invention has no particular limitation thereto.

### Second Embodiment

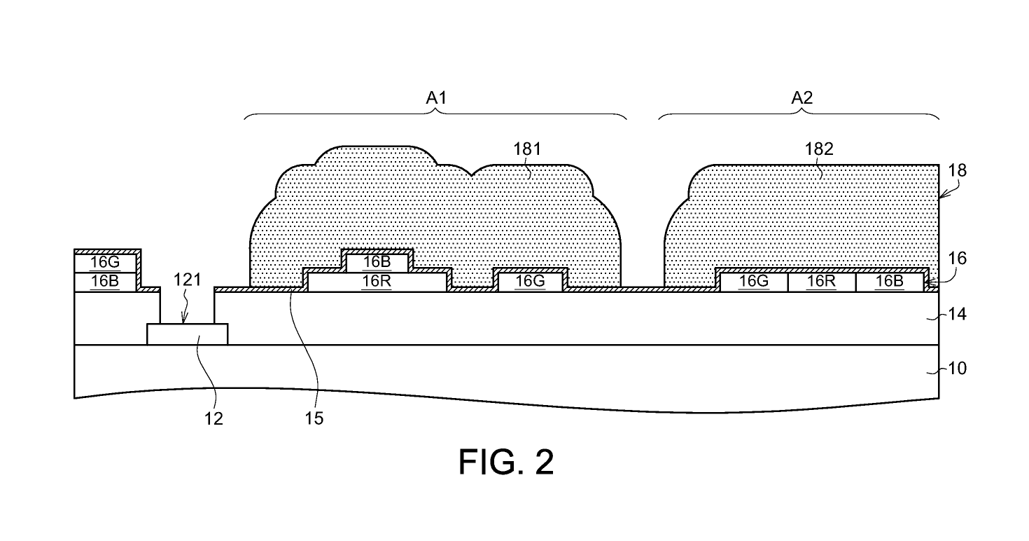

FIG. 2 illustrates a light detecting device according to a second embodiment of the present disclosure. The light detecting device of the second embodiment is similar to that of the first embodiment, except for formation of an inter-layer. The first embodiment illustrates a light detecting device without forming an inter-layer, while the second embodiment illustrates another light detecting device with an inter-layer 15 formed for capping the color filter elements. Please also refer to FIG. 1 and related descriptions of the first embodiment, and the similar contents are not redundantly repeated here.

In the second embodiment, an inter-layer 15 is formed on the passivation layer 14, such as entirely covering the color filter elements 16 but revealing the exposed portions (ex: metal pad 121) of the patterned metal layer 12. Then, the patterned inorganic light filter film 18 is formed on the inter-layer 15. Thus, the inter-layer 15 is positioned between the color filter elements 16 and the patterned inorganic light filter film 18.

As shown in FIG. 2, the inter-layer 15 caps all of the CF elements 16 in the first light detecting region A1 and the second light detecting region A2, wherein the first inorganic film 181 and the second inorganic film 182 are formed on the inter-layer 15 and corresponding to the first light detecting region A1 and the second light detecting region A2, respectively. In one embodiment, the inter-layer 15 can be photoresist as a planar layer, tetraethoxysilane (TEOS), SiO2, a silicon-rich oxide (SRO), a plasma-enhanced oxide (PE-oxide), spin on glass (SOG) film, or the combination thereof. In one embodiment, the inter-layer 15 can be formed by a low temperature chemical vapor deposition (CVD) process.

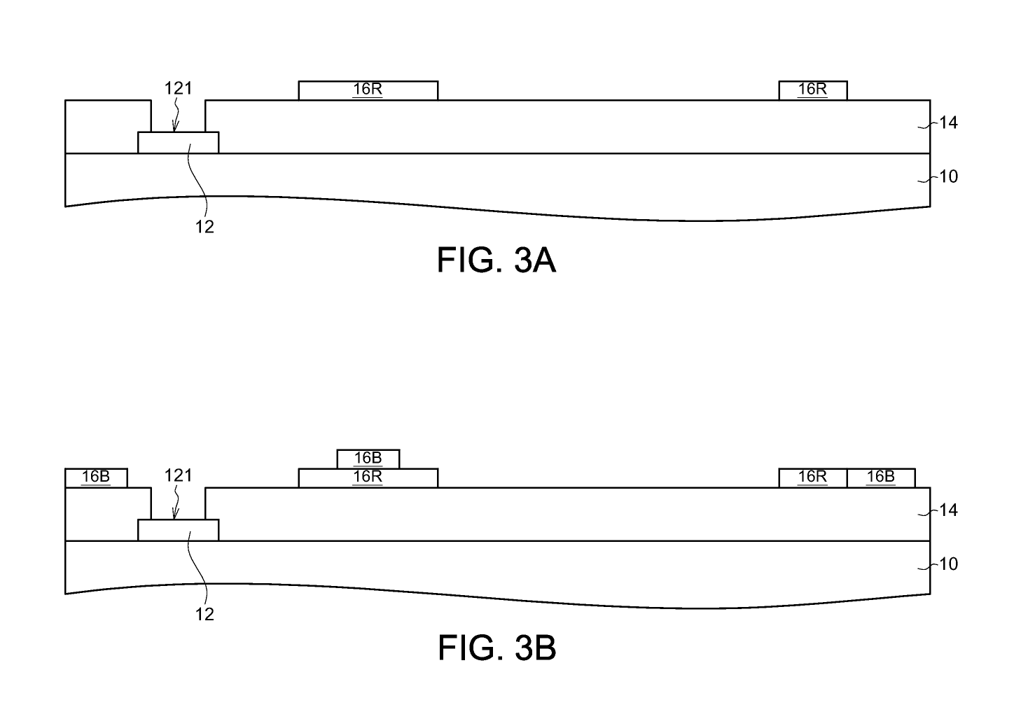

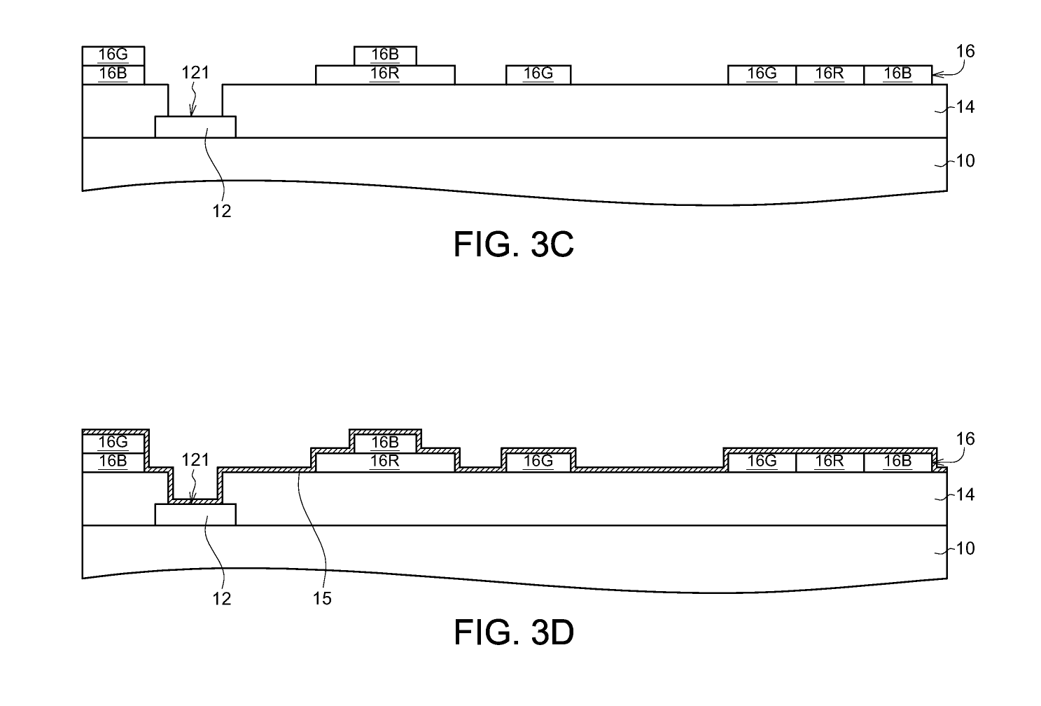

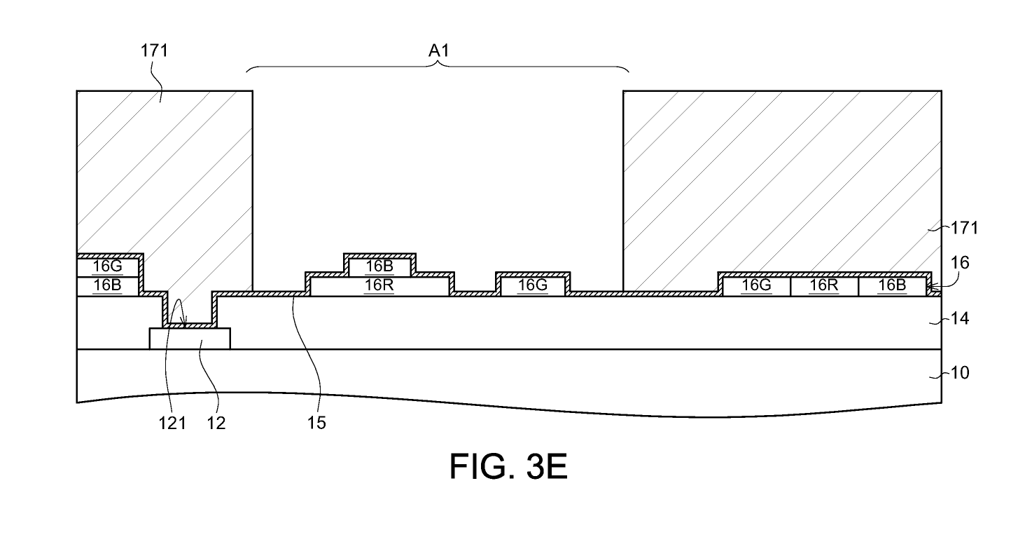

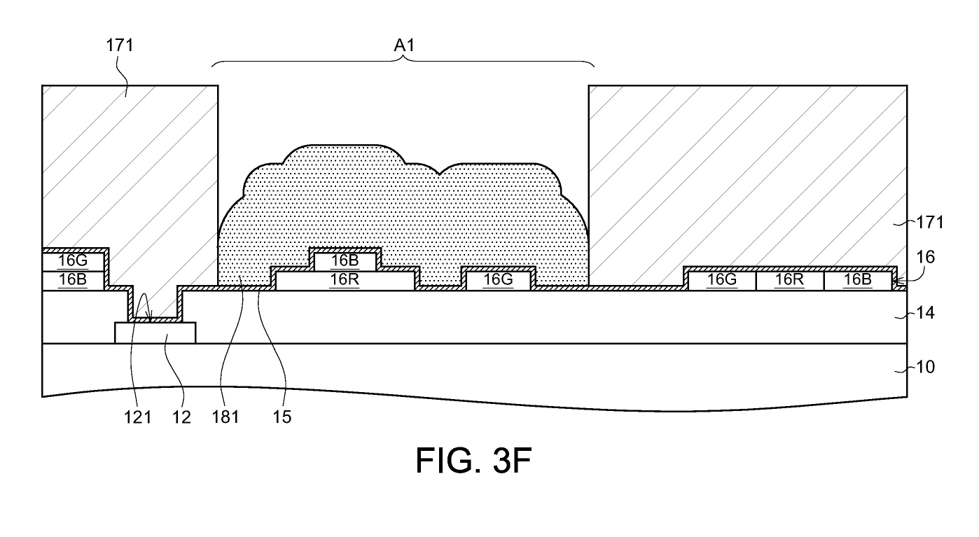

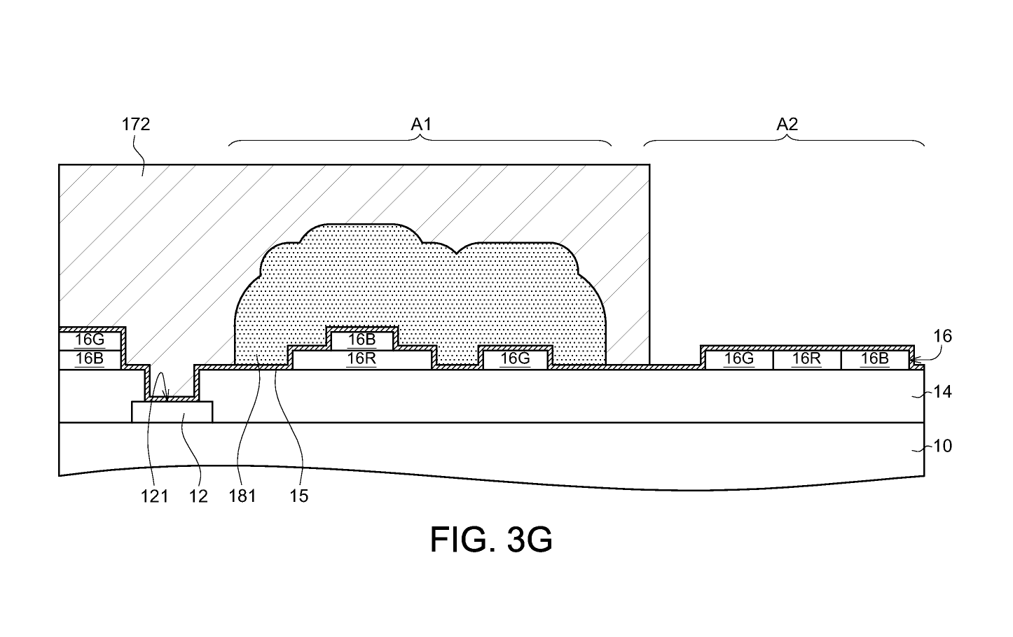

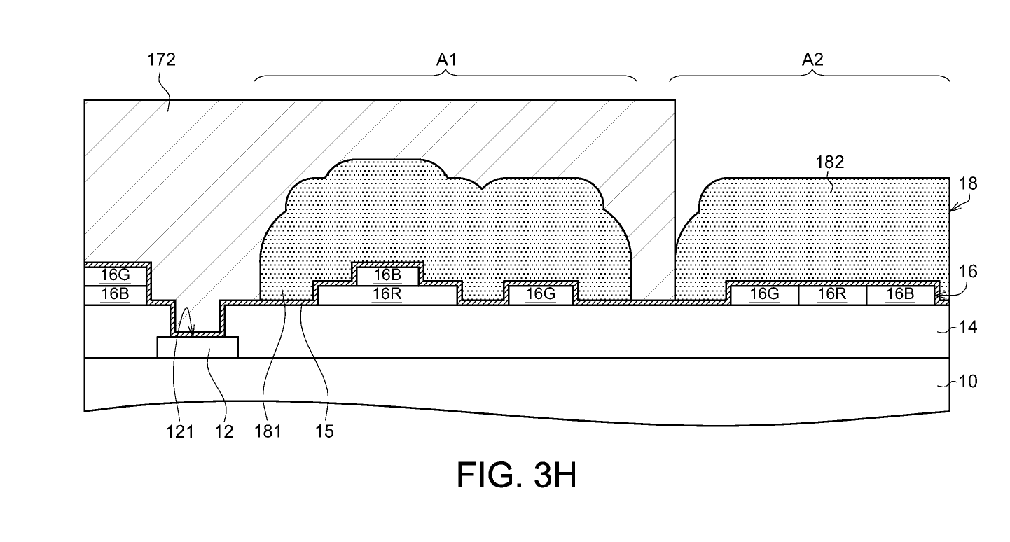

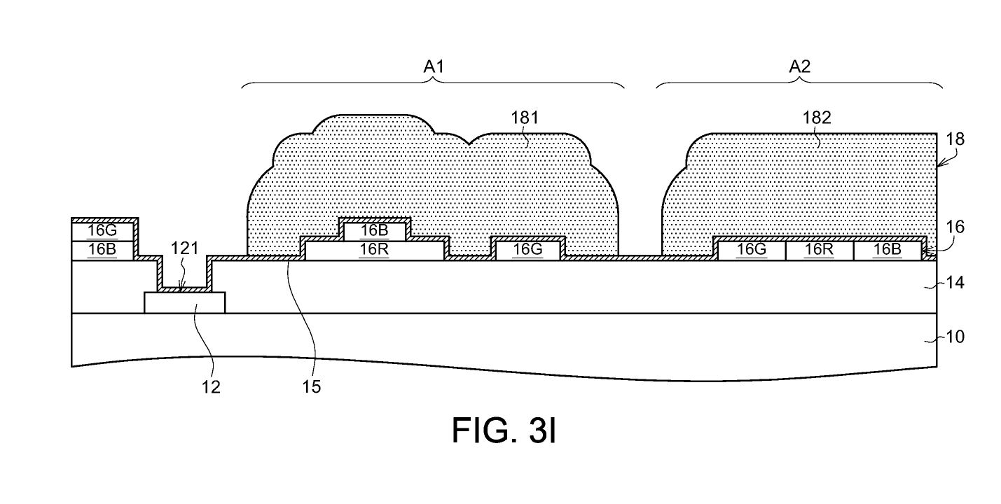

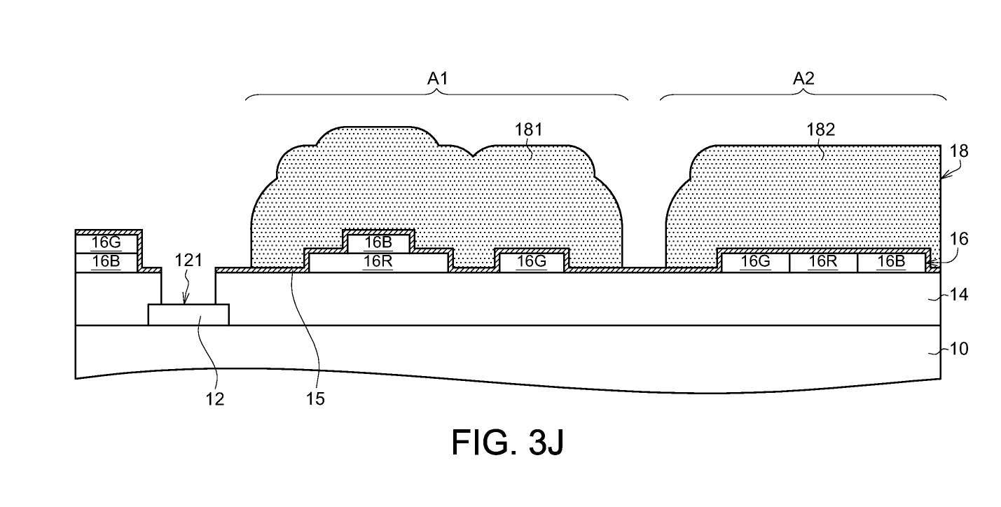

FIG. 3A to FIG. 3J illustrate a method for manufacturing a light detecting device according to the second embodiment of the present disclosure. First, a substrate 10 with a patterned metal layer 12 formed there above is provided, followed by forming a passivation layer 14 above the substrate 10 and exposing portions of the patterned metal layer 12. Then, a plurality of color filter elements 16 is formed on the passivation layer 14. As shown in FIG. 3A, a red color filter (CF) layer comprising plural red filter elements 16R (or any other color such as blue or green filter elements) is formed on the passivation layer 14. As shown in FIG. 3B, a blue color filter layer comprising plural blue filter elements 16B (or any other color such as red or green filter elements) is formed on the passivation layer 14; for example, a stack of the color filter elements with different colors (ex: blue and red) is constructed in the first light detecting region A1. As shown in FIG. 3C, a green color filter layer comprising plural green filter elements 16G (or any other color such as red or blue filter elements) is formed on the passivation layer 14. According to this embodiment, the green, red and blue filter elements (16G, 16R and 16B) are arranged as an array in the second light detecting region A2. It is noted that the formation and arrangements of the red, green and blue filter elements 16R, 16G and 16B in FIG. 3A to FIG. 3C can be varied according to the practical applications.

In one embodiment, a thickness of the red, green and blue filter elements 16R, 16G and 16B is in a range of 0.5 μm-2.5 μm. In one embodiment, the color filter elements 16 are formed at a temperature ranged from 25° C. to 280° C. For example, the CF elements 16 are coated at room temperature, and post baked at a higher temperature up to 280° C.

Then, an inter-layer 15 is formed to entirely cover the color filter elements 16 and the metal pad 121, as shown in FIG. 3D. The inter-layer 15 (such as the planar (photoresist), oxide, etc.) protects the color filter elements 16 from being damaged in the process of forming an inorganic film subsequently. In one embodiment, a thickness of the inter-layer 15 (may including a planar layer and oxide) is in a range of 1 KÅ-30KÅ. In one embodiment, the inter-layer 15 can be deposited on the passivation layer 14 at a temperature ranged from 100° C. to 300° C.

Afterward, a patterned inorganic light filter film 18 (ex: a multi-layered film) is formed on the inter-layer 15. In this embodiment, formation of the first inorganic film 181 followed by formation of the second inorganic film 182 is exemplified for illustrating one of applicable processes.

As shown in FIG. 3E, a first patterned photo-resist (PR) 171 is formed for defining an area for forming the first inorganic film 181. In one embodiment, the first patterned photo-resist (PR) 171 covers the second light detecting region A2 and the metal pad 121.

As shown in FIG. 3F, the first inorganic film 181 is deposited on the inter-layer 15. In one embodiment, the first inorganic film 181 is deposited correspondingly to the first light detecting region A1 such as an ambient light sensor (ALS) region. Alternatively, the first inorganic film 181 can be deposited correspondingly to an ALS region and an image sensor region. The first patterned photo-resist (PR) 171 can be removed after formation of the first inorganic film 181.

As shown in FIG. 3G, a second patterned photo-resist (PR) 172 is formed for defining an area for forming the second inorganic film 182.

As shown in FIG. 3H, the second inorganic film 182 is deposited on the inter-layer 15. The second inorganic film 182 can be formed by using the manufacturing step same as for forming the first inorganic film 181.

As shown in FIG. 3I, the second patterned photo-resist (PR) 172 is removed, and a patterned inorganic light filter film 18 (comprising the first inorganic film 181 and the second inorganic film 182) is formed. In one embodiment, a thickness of a patterned inorganic light filter film 18 is in a range of 2 μm-7 μm.

Then, the metal pad 121 is reopened, by removing the portion of the inter-layer 15 deposited on the surface of the metal pad 121, as shown in FIG. 3J (identical to FIG. 2).

There are several applicable materials of the first inorganic film 181 and the second inorganic film 182. For example, some types of the inorganic light filter film may filter infrared light, or allow passing of infrared light, such as the color filter materials for passing light wavelength of 550+/−100 nm (visible light) (BP550, also known as IR-cut), passing light wavelength>850 nm (BP850), passing light wavelength>950 nm (BP950), etc. Color filter material selection depends on the to-be-achieved purposes of the light filter films at the specific regions, and the invention has no particular limitation thereto.

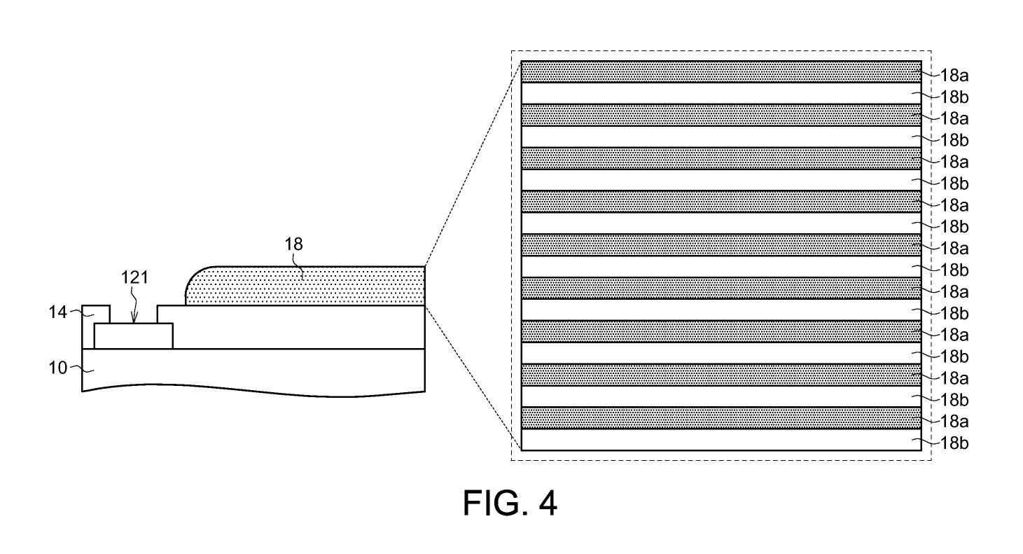

Additionally, an inorganic layer, for forming the patterned inorganic light filter film 18 above the color filter elements 16, is a single film or a multi-layered film. FIG. 4 illustrates a portion of a patterned inorganic light filter film of a light detecting device according to the embodiment. The patterned inorganic light filter film 18 may comprise plural first inorganic material layers 18a and plural second inorganic material layers 18b stacked alternately. A first dielectric coefficient (k1) of the first inorganic material layers 18a is different from a second dielectric coefficient (k2) of the second inorganic material layers 18b. Also, the first inorganic material layers 18a may have the same or different thicknesses, and the second inorganic material layers 18b may have the same or different thicknesses. Thickness of each of the first and second material layers 18a/18b can be adjusted to meet the wavelength requirement of the light filter, depending on actual needs of the practical applications. Light transmittance characteristic can be tuned by number of the first and second inorganic material layers 18a/18b.

In one embodiment, the patterned inorganic light filter film 18 may comprise a number of TiₓO_{y} layers (ex: the first inorganic material layers 18a) and SiₐO_{b} layers (ex: the second inorganic material layers 18b) stacked alternately. In another embodiment, the patterned inorganic light filter film 18 may comprise a number of SiₓN_{y} layers (ex: the first inorganic material layers 18a) and SiₐO_{b} layers (ex: the second inorganic material layers 18b) stacked alternately.

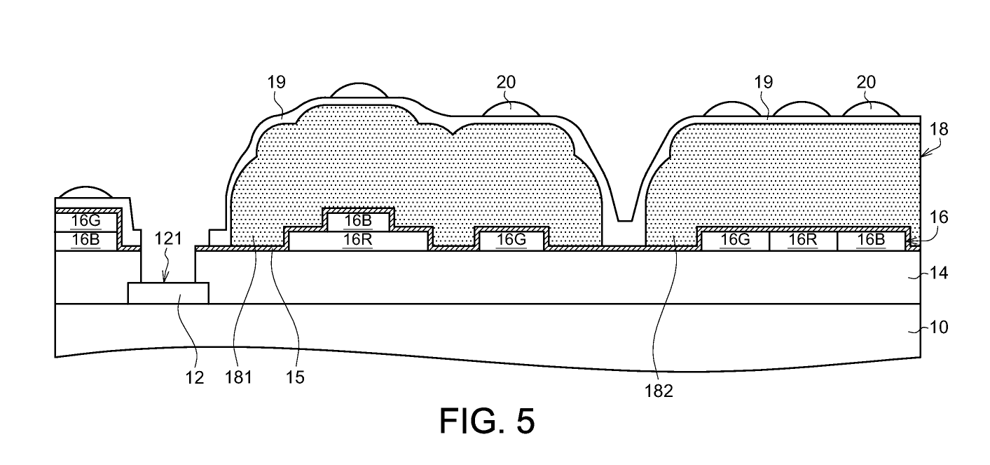

Additionally, the micro-lens could be formed after or before forming the patterned inorganic light filter film 18. FIG. 5 illustrates a light detecting device with micro-lens according to the second embodiment. As shown in FIG. 5, the micro-lens 20 are formed after forming the patterned inorganic light filter film 18; for example, forming the patterned PR as the micro-lens 20 stacked above the first inorganic film 181 and the second inorganic film 182. Also, a planar layer 19 can be optionally formed for covering the patterned inorganic light filter film 18, and the micro-lens 20 is formed on the planar layer 19, thereby improving the uniformity and configuration of the micro-lens 20.

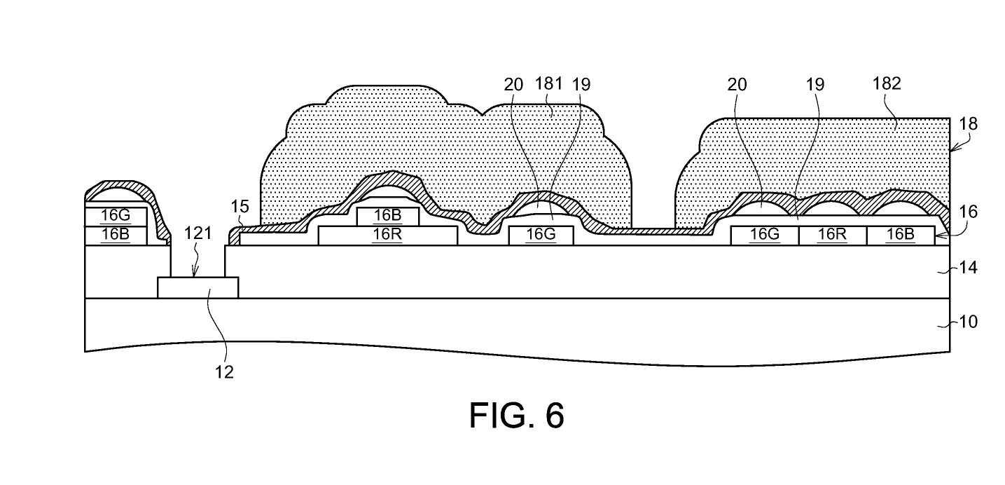

FIG. 6 illustrates another light detecting device with micro-lens according to the second embodiment. In an alternative embodiment, a planar layer 19 is formed on the color filter elements 16, the micro-lens 20 are formed (above the color filter elements 16) on the planar layer 19, and the inter-layer 15 covers the micro-lens 20 as a protection layer. Noted that the patterned inorganic light filter film 18 should be formed above the micro-lens 20 at a temperature without deforming the micro-lens.

According to the aforementioned description, the light detecting device having the light filter film (made by the inorganic material) formed after the color filter array (CFA) (made by the organic material) possesses several advantages, such as no damage occurring to the color filter array in any back-end processes (such as NMP, plasma, solvent treatments, pad re-open step, etc), no defects of rough surface caused by the thick films (typically occurred in the conventional structure) so that better CFA coating control and uniformity can be created, and CFA coating without worrying poor coating of the color filter array). Also, the manufacturing method of the embodiment is simple and easy, which is time-saving and able to maintain a low production cost. Thus, the structure and manufacturing method provided in the embodiments not only improve the production yield of the light detecting device but also achieve a better optical performance since no defect occurred in the CFA and the patterned inorganic light filter film.

Other embodiments with different configurations such as patterns of the color filter elements, the patterned inorganic light filter film and the inter-layer can be applicable, and the variations depend on the actual needs of the practical applications. It is, of course, noted that the configurations of Figures are depicted only for demonstration, not for limitation. It is known by people skilled in the art that the shapes or positional relationship of the constituting elements could be adjusted according to the requirements and/or manufacturing steps of the practical applications.

While the disclosure has been described by way of example and in terms of the exemplary embodiment(s), it is to be understood that the disclosure is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A light detecting device, comprising:
a patterned metal layer formed above a substrate;
a passivation layer formed above the substrate and exposing portions of the patterned metal layer;
a plurality of color filter elements formed on the passivation layer; and
a patterned inorganic light filter film formed above the color filter elements.

2. The light detecting device according to claim 1, further comprising an inter-layer formed on the passivation layer and outside of the exposed portions of the patterned metal layer, wherein the inter-layer is positioned between the color filter elements and the patterned inorganic light filter film.

3. The light detecting device according to claim 2, wherein the inter-layer entirely covers the color filter elements.

4. The light detecting device according to claim 2, wherein the inter-layer comprises at least one of a planar layer, SiO2, tetraethoxysilane (TEOS), a silicon-rich oxide (SRO), a plasma-enhanced oxide (PE-oxide) and a spin on glass (SOG) film.

5. The light detecting device according to claim 2, wherein the inter-layer is formed by a low temperature chemical vapor deposition (CVD) process.

6. The light detecting device according to claim 2, wherein the inter-layer is deposited on the passivation layer at a temperature ranged from 100° C. to 300° C.

7. The light detecting device according to claim 2, wherein a thickness of the inter-layer is in a range of 1 KÅ-30KÅ.

8. The light detecting device according to claim 7, wherein a thickness of each of the color filter elements is in a range of 0.5 μm-2.5 μm.

9. The light detecting device according to claim 1, wherein the patterned inorganic light filter film comprises:
a first inorganic film, formed at a first light detecting region with at least one stack of the color filter elements; and
a second inorganic film, formed at a second light detecting region with the color filter elements arranged in an array.

10. The light detecting device according to claim 9, further comprising an inter-layer capping all of the color filter elements in the first and second light detecting regions, wherein the first and second inorganic films are formed on the inter-layer and corresponding to the first and second light detecting regions, respectively.

11. The light detecting device according to claim 9, wherein the second inorganic film is separated from the first inorganic film.

12. The light detecting device according to claim 1, wherein the patterned inorganic light filter film is a multi-layered film.

13. The light detecting device according to claim 1, wherein the patterned inorganic light filter film at least comprises plural first inorganic material layers and second inorganic material layers stacked alternately, and a first dielectric coefficient (k1) of the first inorganic material layers is different from a second dielectric coefficient (k2) of the second inorganic material layers.

14. A method for manufacturing a light detecting device, comprising:
providing a substrate with a patterned metal layer formed there above;
forming a passivation layer above the substrate and exposing portions of the patterned metal layer;
forming a plurality of color filter elements on the passivation layer; and
forming a patterned inorganic light filter film above the color filter elements.

15. The method according to claim 14, further comprising forming an inter-layer on the color filter elements, and the patterned inorganic light filter film being formed on the inter-layer, wherein the inter-layer entirely covers the color filter elements.

16. The method according to claim 15, wherein the inter-layer comprises at least one of a planar layer, SiO2, tetraethoxysilane (TEOS), a silicon-rich oxide (SRO), a plasma-enhanced oxide (PE-oxide) and a spin on glass (SOG) film.

17. The method according to claim 15, wherein the inter-layer is deposited on the passivation layer at a temperature ranged from 100° C. to 300° C.

18. The method according to claim 15, wherein a thickness of the inter-layer is in a range of 1 KÅ-30KÅ.

19. The method according to claim 14, wherein the patterned inorganic light filter film comprises:
a first inorganic film, formed at a first light detecting region with at least one stack of the color filter elements; and
a second inorganic film, formed at a second light detecting region with the color filter elements arranged in an array,
wherein the first inorganic film and the second inorganic film are formed consequently.

20. The method according to claim 19, further comprising forming an inter-layer capping all of the color filter elements in the first and second light detecting regions, wherein the first and second inorganic films are formed on the inter-layer and corresponding to the first and second light detecting regions, respectively.

21. The method according to claim 14, further comprising:
forming micro-lens above the patterned inorganic light filter film.

22. The method according to claim 21, further comprising:
forming a planar layer for covering the patterned inorganic light filter film, wherein the micro-lens is formed on the planar layer.

23. The method according to claim 14, further comprising: forming micro-lens on the color filter elements, wherein the patterned inorganic light filter film is formed on the micro-lens at a temperature without deforming the micro-lens.
